(19) United States
(12) Patent Application Publication
(10) Pub. No.: US 2009/0091918 A1
(43) Pub. Date: Apr. 9, 2009

(54) ORGANIC ELECTRO-LUMINESCENCE ELEMENT, PRODUCTION METHOD AND USE THEREOF

(75) Inventor: Tamami Koyama, Chiba (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 12/064,873

(22) PCT Filed: Aug. 23, 2006
(86) PCT No.: PCT/JP2006/317030

§ 371 Date: Feb. 26, 2008

Related U.S. Application Data
(60) Provisional application No. 60/713,742, filed on Sep. 6, 2005.

(30) Foreign Application Priority Data
Aug. 26, 2005 (JP) 2005-245779

(51) Int. Cl. G09F 13/08; B05D 5/06; H01J 1/62

(52) U.S. Cl. 362/97.1; 427/66; 313/504

(57) ABSTRACT

Disclosed is an organic electro-luminescence element including an anode layer, an organic electro-luminescence compound layer containing a high molecular weight light-emitting compound, and a cathode layer, laminated in this order, wherein said cathode layer includes: (i) a metal-doped electron injection layer in contact with the organic electro-luminescence compound layer and (ii) a transparent, non-metallic electron-injecting material in contact with the metal-doped electron injection layer; and wherein said metal-doped electron injection layer is selected from the group consisting of a material functioning as a hole-blocking material, a material functioning as an exciton-blocking material and a material functioning as a blocking material for both holes and excitons.

### CROSS REFERENCES OF RELATED APPLICATIONS

This application is an application filed under 35 U.S.C. §111(a) claiming benefit pursuant to 35 U.S.C. §119(e) (1) of the filing dates of Provisional Application 60/713,742 filed Sep. 6, 2005 pursuant, to 35 U.S.C. §111(b).

### TECHNICAL FIELD

The present invention relates to a highly efficient and highly transparent organic electro-luminescence (hereinafter, also referred to as organic EL) element using a cathode comprising a transparent, non-metallic, electron-injecting cathode layer such as ITO, and a metal-doped organic electron injection layer that also functions as an exciton-blocking layer and/or as a hole-blocking layer.

### BACKGROUND ART

In organic EL elements, the mechanism of light emission is typically based on the radiative recombination of injected electrons and holes. Specifically, organic EL elements comprise at least one kind of thin organic layer separating the anode and the cathode. As a material contained in this organic layer, there may be mentioned a hole-transporting material selected according its ability to assist in injecting and transporting holes, an electron-transporting material selected according to its ability to assist in injecting and transporting electrons, and a luminescent material that emits light on injection of holes and/or electrons.

With such a construction, the organic EL element can be viewed as a diode with a forward bias when the potential applied to the anode is more positive than the potential applied to the cathode. Under these bias conditions, the anode injects holes (positively charged carriers) into the hole-transporting layer, while the cathode injects electrons into the electron-transporting layer. Accordingly, the portion of the luminescent medium adjacent to the anode forms a hole-injecting and transporting zone while the portion of the luminescent medium adjacent to the cathode forms an electron-injecting and transporting zone. The injected holes and electrons each migrate toward the oppositely charged electrode. A Frenkel exciton is formed when an electron and a hole are localized on the same molecule. One may consider this short-lived state as having an electron that can drop (relax) from its conduction potential to a valence band, with relaxation occurring, under certain preferred conditions, by a photoelectric emission mechanism. Adopting this concept of the typical mechanism for operation of thin-layer organic EL elements, the organic EL compound layer comprises a luminescence zone receiving mobile charge carriers (electrons and holes) from the electrodes (cathode and anode).

One of the shortcomings in these organic EL elements has been the transparency of the cathode. A high quantum efficiency is achieved using a metal layer with a low work function such as magnesium-silver (Mg—Ag) or calcium, or a compound electrode such as LiF—Al or LiAl, but the metal layer must be made thin enough to achieve a satisfactory transparency, because metal layers are also highly reflective and absorptive in the visible region of the spectrum. For example, a conventional transparent organic EL element uses a 7.5 nm-10 nm Mg—Ag layer capped with a thicker layer of transparent ITO deposited on it. Although an organic EL element with about 70% transmission may be obtained, there is still significant reflection from the compound cathode. In addition, in stacked organic EL elements in which at least one of the color producing layers is contained between the metallic cathodes of adjacent color producing organic EL elements, microcavity effects are present which can give rise to color tuning problems (Z. Shen, P. E. Burrows, V. Bulovic, S. R. Forrest, and M. E. Thompson, Science 276, 2009 (1997)). Suchmicrocavity effects may also lead to an undesired angular dependence of the emitted light. Furthermore, thin Mg—Ag layers are sensitive to atmospheric degradation, and special designs and processing steps are, therefore, required so as to preserve their effectiveness in functioning as the cathodes of organic EL elements.

In organic EL elements where a still higher level of transparency is desired, a compound cathode comprising a non-metallic cathode and an organic interface layer can be used [Parthasarathy, P. E. Burrows, V. Khalin, V. G. Kozlov, and S. R. Forrest, Appl. Phys. Lett. 72, 2138 (1998); (Parthasarathy I)]. The representative transparent organic EL elements comprising tris(8-hydroxyquinoline)aluminum (hereafter also referred to as Alq₃) as a base material disclosed by Parthasarathy I, due to the absence of a metallic cathode layer, emitted nearly identical light levels in the forward and back scattered directions. Optical transmission of at least about 85% was achieved using this non-metallic, compound cathode. However, the quantum efficiency of a device fabricated with such a cathode is typically reduced in the range of about 0.1% to 0.3% compared to organic EL elements using the Mg—Ag-ITO cathode of Forrest et al. (U.S. Pat. No. 5,703,436 specification) wherein the device efficiency was about 1% but the transmission was only about 70%. Therefore, the non-metallic cathode improves transparency but deteriorates device efficiency. A cathode that is both highly transparent and highly efficient would be preferred.

It is known that the quantum efficiency of an organic EL element can be increased by using a metal-doped organic layer in the organic EL element as an electron-injecting layer at the interface between a metal cathode and an emitter layer. A lithium-doped Alq₃ layer generates radical anions of Alq₃ serving as intrinsic electron carriers, which result in a lower barrier height for electron-injecting and a higher electron conductivity of the lithium doped Alq₃ layer (J. Kido and T. Matsumoto, Applied Physics Letters, v. 73, n. 20, 2866 (1998)). This improved quantum efficiency, but the organic EL element was not transparent.

A compound cathode comprising a layer of lithium-doped CuPc (copper phthalocyanine) in contact with an emitter layer such as α-napithylphenylbiphenyl (α-NPB), and a layer of ITO as a conductive layer achieved an improved transparency and a slightly improved quantum efficiency, but its efficiency was lower than relatively non-transparent metal cathodes (L. S. Hung and C. W. Tang, Applied Physics Letters, v. 74, n. 21, 3209 (1999).).

As an organic EL element employing a compound cathode that has similar level of transparency to that of a compound cathode using ITO and CuPc or lithium-doped CuPc and quantum efficiency similar to that of a metal cathode, Japanese translation of a PCT application 2003-526188 (Patent document 1) specifically disclosed an organic EL element employing a compound cathode comprising a layer of ITO and a layer of lithium-doped 2,9-dimethyl-4,7-diphenyl-1,10-phenanthroline (hereafter also referred to as BCP).

Although this organic EL element was excellent in having high efficiency and high transparency over the entire visible spectrum, because the organic EL compound layer specifically disclosed in this literature had a structure wherein a layer of 4,4′-bis[N-(1-naphthyl)-N-phenylamino]biphenyl (hereafter also referred to as NPD) and a layer of tris(8-hydroxyquinoline)aluminum (Alq₃) were stacked, there has been a problem of difficulty in controlling the film thickness or the number of stacked layers which results in low productivity.

Patent document 1; Japanese translation of a PCT application 2003-526188

### DISCLOSURE OF THE INVENTION

The present invention is directed toward solving the above-mentioned problems of the conventional technologies and has as an object to provide an organic EL element that has high quantum efficiency, high transparency and also excellent productivity by employing a compound cathode.

The present inventors have pursued zealous study to solve the above-mentioned problems and achieved the present invention. The present invention relates to the following [1] to [32].

[1]

An organic EL element comprising an anode layer, an organic EL compound layer containing a high molecular weight light-emitting compound, and a cathode layer, laminated in this order,

wherein said cathode layer comprises:

(i) a metal-doped electron injection layer in contact with the organic EL compound layer and

(ii) a transparent, non-metallic electron-injecting material in contact with the metal-doped electron injection layer; and

wherein said metal-doped electron injection layer is selected from the group consisting of a material functioning as a hole-blocking material, a material functioning as an exciton-blocking material and a material functioning as a blocking material for both holes and excitons.

[2]

The organic EL element described in [1], wherein the metal-doped electron injection layer also functions as an exciton-blocking layer.

[3]

The organic EL element described in [1], wherein, the metal-doped electron injection layer also functions as a hole-blocking layer.

[4]

The organic EL element described in [1], wherein the metal-doped electron injection layer is doped with a metal selected from the group consisting of Li, Sr and Sm.

[5]

The organic EL element described in [1], wherein the metal-doped electron injection layer is doped with Li.

[6]

The organic EL element described in [1] or [5], wherein the metal-doped electron injection layer comprises 2,9-dimethyl-4,7-diphenyl-1,10-phenanthroline.

[7]

The organic EL element described in [1], wherein the metal-doped electron injection layer has a metal atom density sufficient to produce an electronic density of at least 11¹⁵/cm³.

[8]

The organic EL element described in [1], wherein the metal-doped electron injection layer has a metal atom density sufficient to produce an electronic density of at least 10²¹/cm³.

[9]

The organic EL element described in [1], wherein the metal-doped electron injection layer has a metal atom density sufficient to produce a total external quantum efficiency of at least 1% for the above-mentioned organic EL element.

[10]

The organic EL element described in any one of [1] to [9], wherein the organic EL compound layer comprises a phosphorescent high molecular weight compound.

[11]

The organic EL element described in any one of [1] to [10], wherein the organic EL compound layer comprises a non-conjugated high molecular weight light-emitting compound.

[12]

The organic EL element described in any one of [1] to [11], wherein the organic EL compound layer comprises a phosphorescent non-conjugated high molecular weight compound.

[13]

A surface emitting source equipped with the organic EL element of any one of [1] to [12].

[14]

A backlight for a display device equipped with the organic EL element of any one of [1] to [12].

[15]

A display device equipped with the organic EL element of any one of [1] to [12].

[16]

An illumination device equipped with the organic EL element of any one of [1] to [12].

[17]

Interior goods equipped with the organic EL element of any one of [1] to [12].

[18]

Exterior goods equipped with the organic EL element of any one of [1] to [12].

[19]

A production method of an organic EL element comprising:

preparing, in sequence on a substrate, an anode layer, an organic EL compound layer containing a high molecular weight light-emitting compound, a transparent electron injection layer and a transparent electron-injecting layer,

wherein said transparent electron injection layer is a material selected from the group consisting of a material functioning as a hole-blocking layer, a material functioning as an exciton-blocking layer and a material functioning as a blocking layer for both holes and excitons; and

wherein the preparation comprises a step of doping the transparent electron injection layer with metal to form a metal-doped transparent electron injection layer.

[20]

The production method described in [19] comprising, before forming a film of the transparent electron injection layer, doping the metal into the transparent electron injection layer by vapor depositing an ultra-thin layer of the metal onto the organic electron-transporting layer.

[21]

The production method described in [19] comprising, before forming a film of the transparent electron-injecting layer, doping the metal into the transparent electron injection layer by vapor depositing an ultra-thin layer of the metal onto the transparent electron injection layer.

[22]

The production method described in [19], wherein the electron-injecting layer comprises ITO.

[23]

The production method described in [20], wherein the thickness of the ultra-thin layer of metal is 0.5-1.0 nm.

[24]

The production method described in [20], wherein the metal comprises a metal selected from the group consisting of Li, Sr and Sm.

[25]

The production method described in [20], wherein the metal comprises Li.

[26]

The production method described in [19], wherein the metal-doped transparent electron injection layer comprises 2,9-dimethyl-4,7-diphenyl-1,10-phenanthroline.

[27]

The production method described in [19], wherein the metal-doped transparent electron injection layer has a metal atom density sufficient to produce an electronic density of at least 10¹⁵/cm³.

[28]

The production method described in [19], wherein the metal-doped transparent electron injection layer has a metal atom density sufficient to produce an electronic density of at least 10²¹/cm³.

[29]

The production method described in [19], wherein the metal-doped transparent electron injection layer has a metal atom density sufficient to produce a total external quantum efficiency of at least 1% for the organic EL element.

[30]

The production method described in any one of [19] to [29], wherein the organic EL compound layer comprises a phosphorescent high molecular weight compound.

[31]

The production method described in any one of [19] to [30], wherein the organic EL compound layer comprises a light-emitting non-conjugated high molecular weight compound.

[32]

The production method described in any one of [19] to [31], wherein the organic EL compound layer comprises a phosphorescent non-conjugated high molecular weight compound.

### EFFECT OF THE INVENTION

The organic EL element of the present invention has high emission efficiency and high level of transparency. In addition, the organic EL compound layer in this element can be formed by coating organic EL compounds wherein the kinds and ratio of a hole-transporting compound, an electron-transporting compound and a light-emitting compound are adjusted, and thus, the productivity is high. This point is particularly advantageous in applying the organic EL element to forming panels.

Further, using the production method of organic EL elements of the present invention, organic EL elements having high emitting efficiency and high transparency can be produced with excellent productivity.

### BRIEF DESCRIPTION OF THE DRAWINGS

FIG. 1 is a drawing of a section for an embodiment of the organic EL element of the present invention.

FIG. 2 is a drawing illustrating a compound cathode comprising an electron-injecting material 6a and a metal-doped electron injection layer 6b.

1 transparent substrate
2 anode
3 hole-transporting layer
4 light-emitting layer
5 electron-transporting layer
6 cathode
6a electron-injecting material
6b metal-doped electron injection layer
10 parts of the organic EL element other than the cathode

### BEST MODE FOR CARRYING OUT THE INVENTION

In the following, the organic EL element, production method and use thereof according to the present invention will be described in more detail.

organic EL Element and Production Method Thereof.

First, each component part of the organic EL element (hereafter also referred to as “organic light-emitting element”) will be explained.

(1) Anode:

The anode is composed of a conductive, optically transparent layer, whose representative is ITO. The anode may also be selected from the group consisting of oxides, nitrides, selenides and sulfides of metals. Further, as an anode, there may be used ITO with good optical transparency on whose surface a thin film of 1 nm-3 nm in thickness of the above-mentioned metal is formed so as not to deteriorate the optical transparency. As method for forming a film of these metals onto the surfaces of the anode material, one may use electron beam deposition method, sputtering method, chemical reaction method, coating method, vacuum deposition method or the like. The thickness of anode is preferably 2-300 nm.

(2) Configuration of Element:

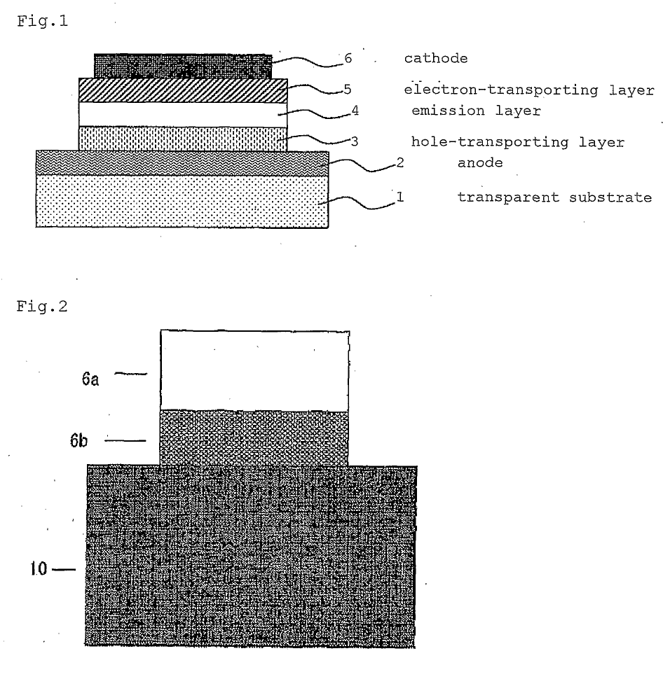

FIG. 1 is a drawing of a cross-sectional view showing one example of configuration of the organic light-emitting element of the present invention, wherein a hole-transporting layer, a light-emitting layer and an electron-transporting layer are successively fabricated between an anode made on a transparent substrate and a cathode.

Further, the configuration of the organic light-emitting element used for the present invention is not limited to the example in FIG. 1. Examples of an element constitution of layers which are successively provided between the anode and the cathode include 1) an anode buffer layer/a hole-transporting layer/a light-emitting layer; 2) an anode buffer layer a light-emitting layer/an electron-transporting layer; 3) an anode buffer layer/a hole-transporting layer/a light-emitting layer/an electron-transporting layer; 4) an anode buffer layer/a layer containing a hole-transporting compound, a light-emitting compound and an electron-transporting compound; 5) an anode buffer layer/a layer containing a hole-transporting compound and a light-emitting compound; 6) an anode buffer layer/a layer containing a light-emitting compound and an electron-transporting compound; 7) an anode buffer layer/a layer containing a hole electron-transporting compound and a light-emitting compound; or other configurations.

Furthermore, though the light-emitting layer as illustrated in FIG. 1 is a single layer, two or more light-emitting layers may be provided. In addition, the layer containing a hole transport material may be brought into direct contact with the surface of the anode without using the anode buffer layer.

Incidentally, in this specification, unless otherwise indicated, a compound composed of all or one or more kind of compound among an electron-transporting compound, a hole-transporting compound and a light-emitting compound is referred to as an organic EL compound, and a layer composed of such compounds is referred to as an organic EL compound layer.

(3) Treatment of Anode Surface:

By treating the anode surface in advance on film formation of a layer containing a hole-transporting compound, performances (adhesion to the anode surface, smoothness of the surface, reduction of barrier for hole injection and the like) of the layer to be overcoated can be improved. Examples of the preliminary treatment method include not only a high frequency plasma treatment but also sputtering method, corona treatment, UV-ozone treatment, oxygen plasma treatment and the like.

(4) Anode Buffer Layer (in Cases Wherein Baytron or the Like is Used):

In the case where the anode buffer layer is prepared by coating by a wet process, the film formation can be carried out using a coating method such as spin coating method, casting method, microgravure coating method, gravure coating method, bar coating method, roll coating method, wire bar coating method, dip coating method, spray coating method, screen printing method, flexo printing method, off-set printing method and inkjet printing method.

The compound usable for film formation by the above-mentioned wet process is not particularly limited if the compound exhibits good adhesion to the anode surface and the organic EL compound contained in the layer over the anode buffer layer. It is preferably to apply anode buffer generally used so far. Examples thereof include conductive polymers such as PEDOT which is a mixture of poly(3,4-ethylenedioxythiophene) and a polystyrenesulfonic acid salt and PANI which is a mixture of polyaniline and a polystyrenesulfonic acid salt. In addition, mixtures resulting from adding an organic solvent such as toluene and isopropyl alcohol in such a conductive polymer may be used. Also, conductive polymers containing a third component such as surfactants are useful. As the surfactant, a surfactant containing one group selected from the group consisting of an alkyl group, an alkylaryl group, a fluoroalkyl group, an alkylsiloxane group, a sulfuric acid salt, a sulfonic acid salt, a carboxylate, an amide, a betaine structure, and a quaternary ammonium group is used. A fluoride based nonionic surfactant is also useful.

(5) organic EL Compound:

As a compound used for the organic EL compound layer, namely the light-emitting layer, the hole-transporting layer and the electron-transporting layer in the organic light-emitting element of the present invention, a high molecular weight compound is used. In the present invention, because the organic EL compound layer is formed, for example, by coating with a high molecular weight compound with a composition adjusted, the productivity of the organic EL element is excellent, and this point is advantageous in forming a panel.

As an organic EL compound which forms an light-emitting layer in the organic light-emitting element of the present invention, there may be mentioned low molecular light-emitting compounds and, high molecular weight light-emitting compounds described in Yutaka Omori, Applied Physics, v. 70, n. 12, 1419-1425 (2001); and the like. Among these, high molecular weight light-emitting compounds are preferred in the point that production process of the element is simplified, and phosphorescent compounds are preferred in the point of high emission efficiency. Accordingly, phosphorescent high molecular weight compounds are further preferred.

High molecular weight light-emitting compounds may be classified into conjugated high molecular weight light-emitting compounds and non-conjugated high molecular weight light-emitting compounds, of which non-conjugated high molecular weight light-emitting compounds are particularly preferred.

For the above-mentioned reasons, as a light-emitting material used in the present invention, a non-conjugated phosphorescent high molecular weight compound (a luminescent material that is the above-mentioned phosphorescent high molecular weight compound and the above-mentioned non-conjugated high molecular weight light-emitting compound) is particularly preferred.

The organic EL compound layer in the organic light-emitting element of the present invention preferably comprises at least one phosphorescent high molecular weight compound containing a phosphorescent, unit, which emits phosphorescence, and a carrier transporting unit, which transports carriers, in one molecule thereof. The phosphorescent high molecular weight compound can be obtained by copolymerizing a phosphorescent compound having a polymerizable substituent and a carrier-transporting compound having a polymerizable substituent. The phosphorescent compound is a metal complex containing a metal selected from the group consisting of iridium, platinum and gold, and an iridium complex is particularly preferred.

As the phosphorescent compound having a polymerizable substituent, there may be mentioned, for example, compounds wherein one or more hydrogen atom(s) in metal complexes represented by the following formulae (E-1) to (E-42) are substituted with polymerizable substituent(s).

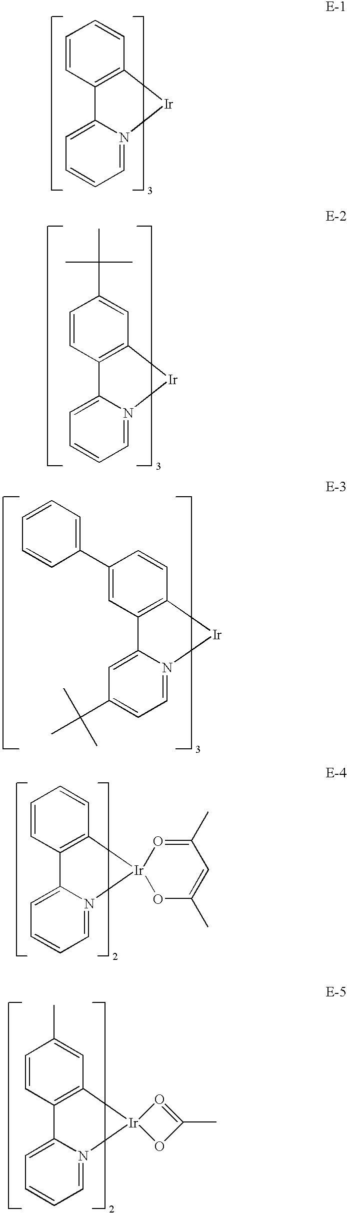

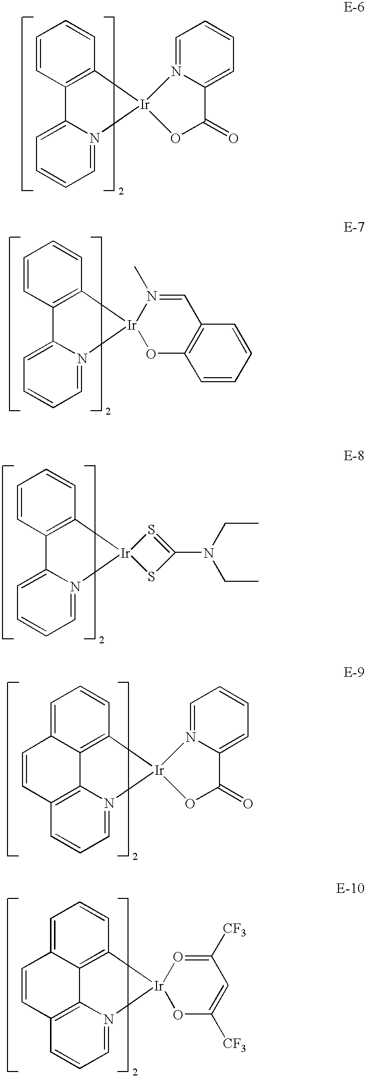

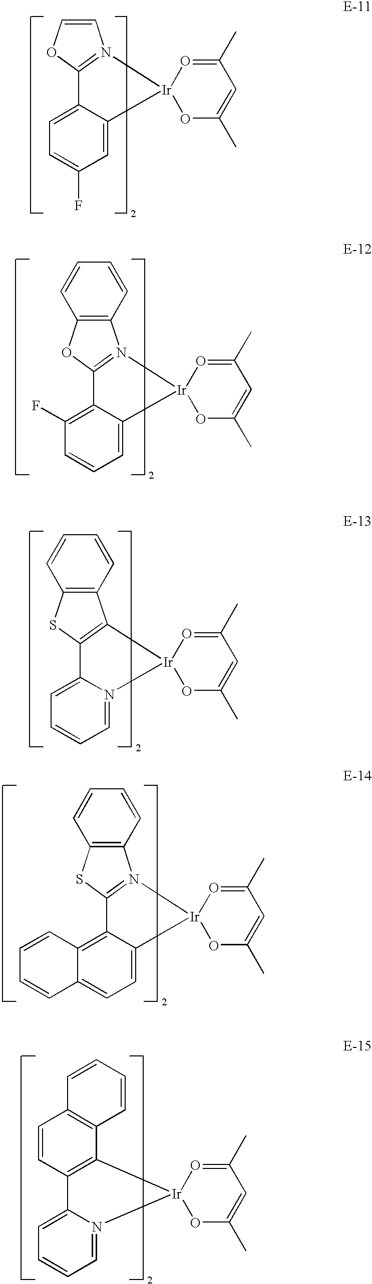

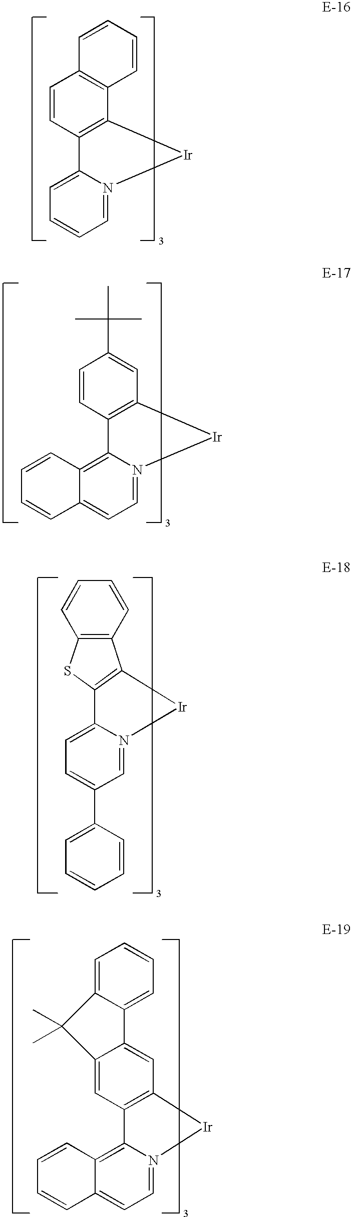

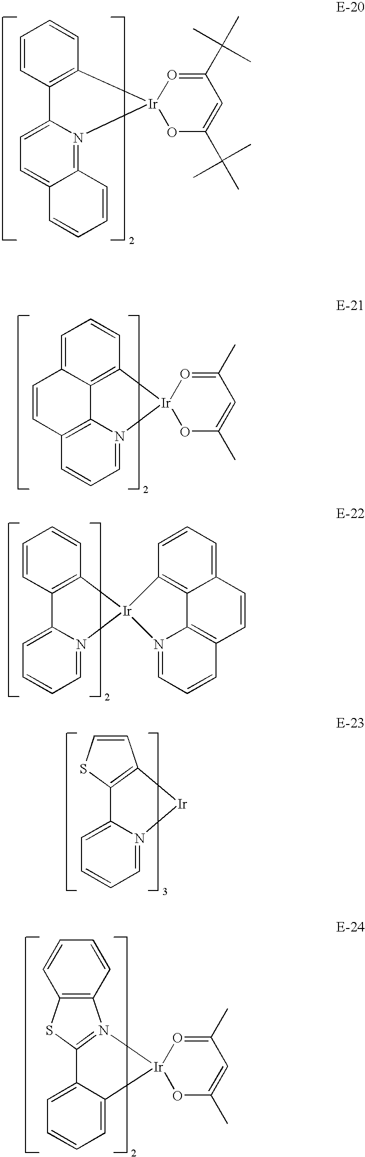

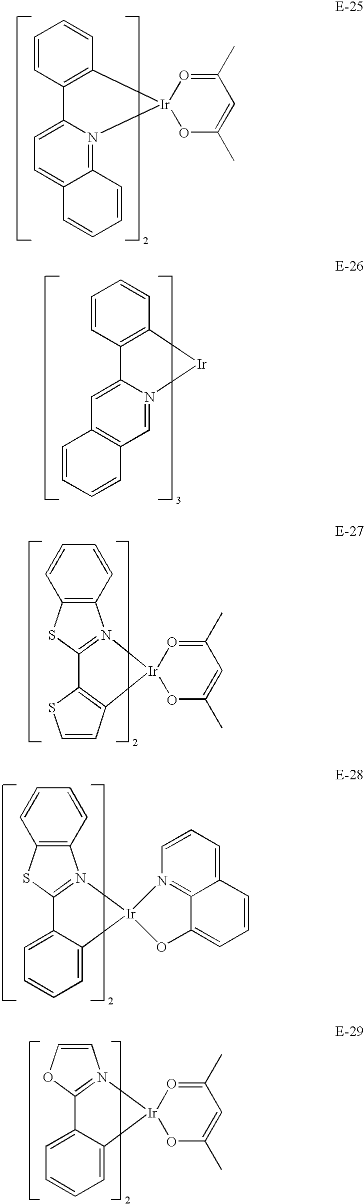

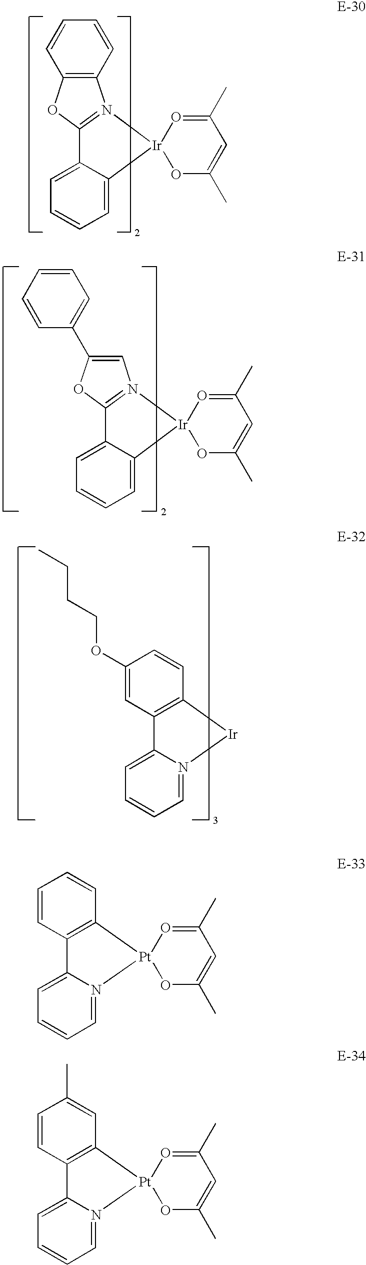

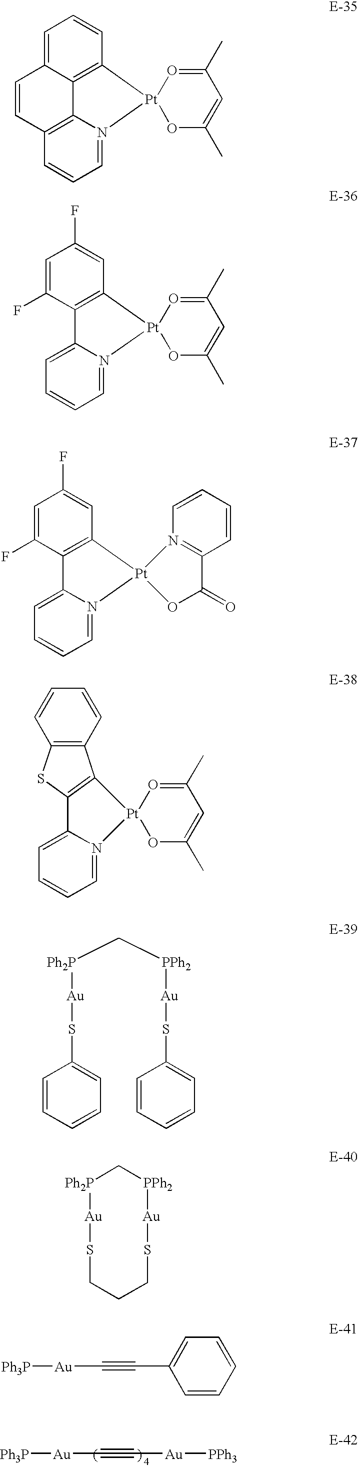

Examples of the substituent in these phosphorescent compounds include a vinyl group, an acrylate group, a methacrylate group, a urethane(meth)acrylate group such as a methacroyloxyethylcarbamate group, a styryl group and derivative thereof and a vinylamide group and derivative thereof. Among these, a vinyl group, a methacrylate group and a styryl group and derivative thereof are particularly preferred. These substituents may bond to the metal complex via an organic group having 1 to 20 carbon atoms and optionally contains a heteroatom.

As the carrier transporting compound having a polymerizable substituent, there may be mentioned, for example, compounds resulting from substituting at least one hydrogen atom of an organic compound having either one or both of hole transport properties and electron transport properties with a polymerizable substituent. As representative example of such a compound, there may be mentioned compounds represented by the following formulae (E-43) to (E-60).

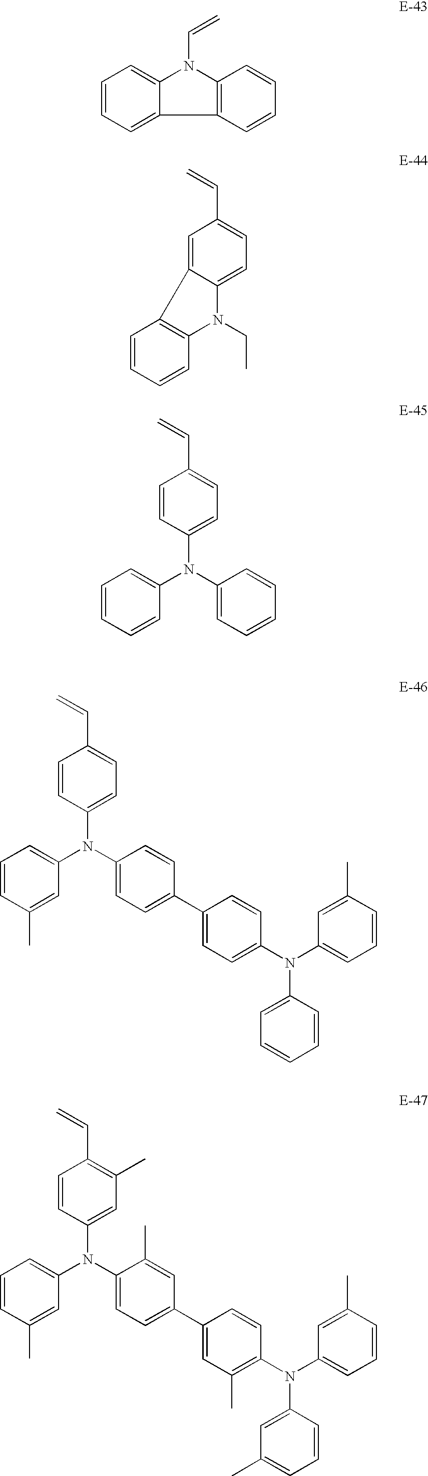

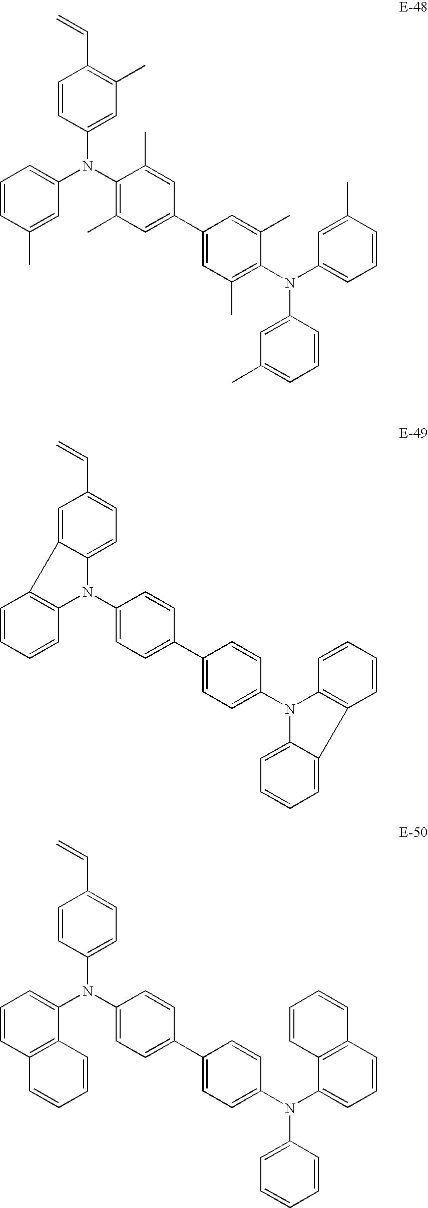

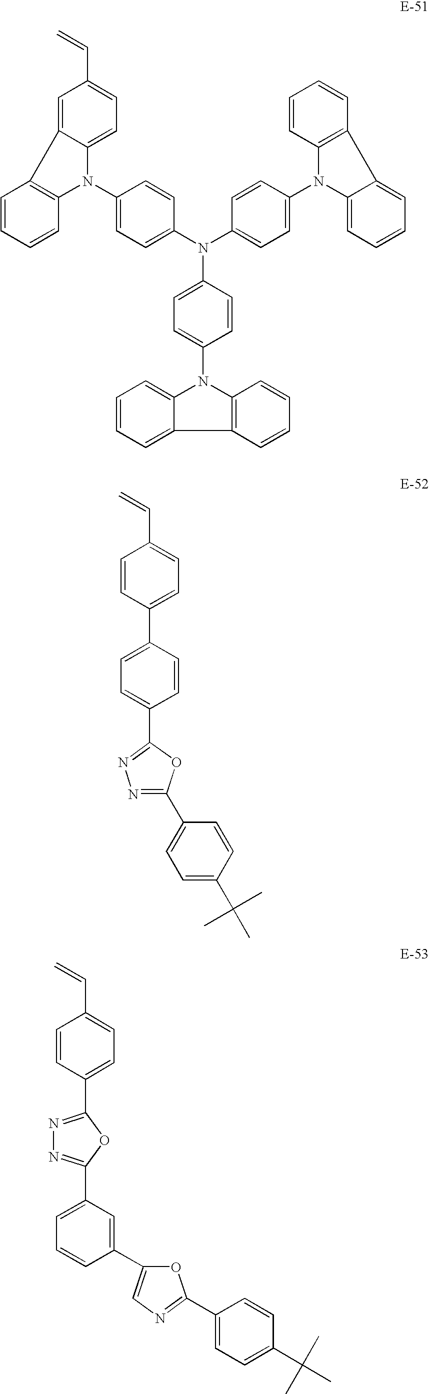

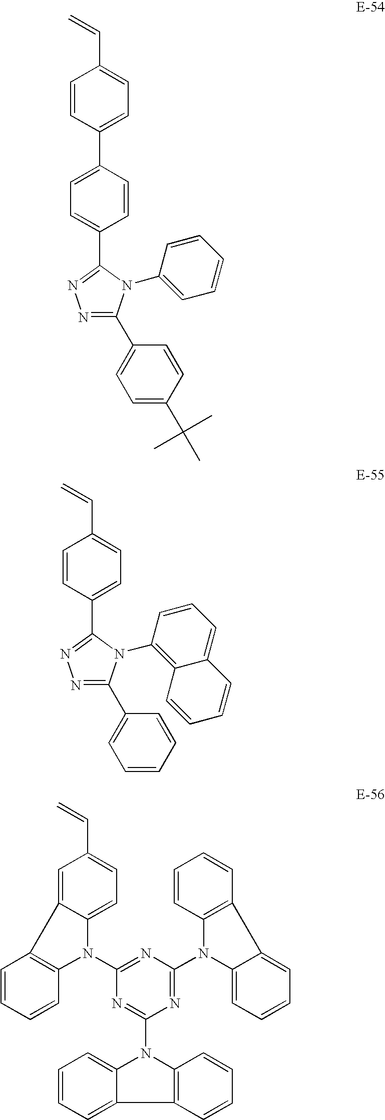

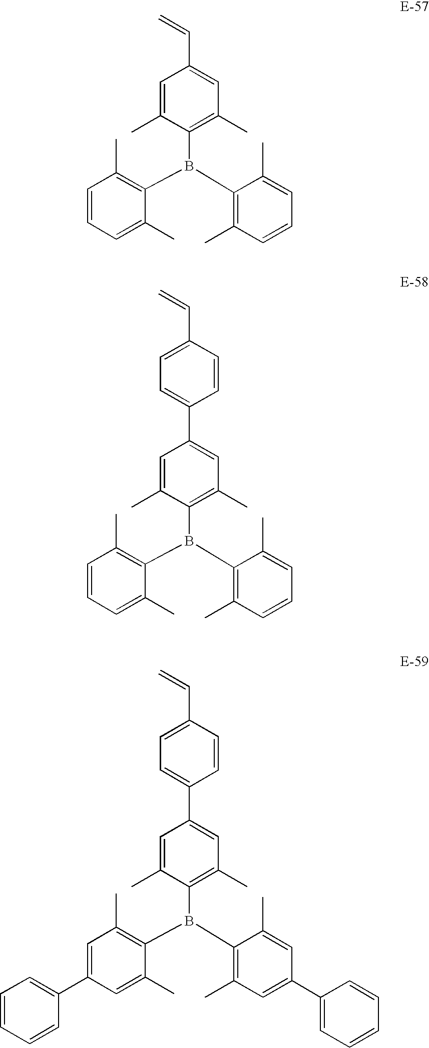

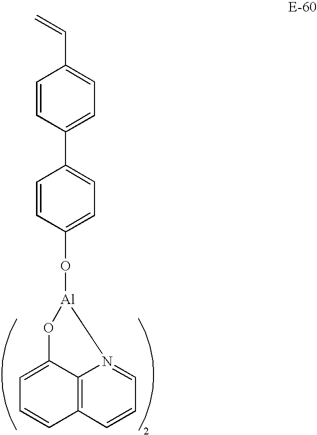

In the above formulae (E-39) to (E-42), Ph represents a phenyl group.

Although the polymerizable substituent is a vinyl group in these exemplified compounds, there may be used compounds wherein the vinyl group is replaced with another polymerizable substituent such as an acrylate group, a methacrylate group, a urethane (meth)acrylate group such as a methacroyloxyethyl carbamate group, a styryl group and derivative thereof, a vinylamide group and derivative thereof or the like. Further, these polymerizable substituents may bond to the metal complex via an organic group which has 1 to 20 carbon atoms and optionally contains a hetero atom.

As method for polymerizing a phosphorescent compound having a polymerizable substituent and a carrier-transporting compound having a polymerizable substituent, one can use any of radical polymerization, cation polymerization, anion polymerization and addition polymerization. Among these, radical polymerization is preferred. As for molecular weight of the polymer, the weight-averaged molecular weight is preferably 1,000-2,000,000, more preferably 5,000-1,000,000. The molecular weight as referred to herein is a molecular weight as reduced into polystyrene as measured using a GPC (gel permeation chromatography) method.

The phosphorescent high molecular weight compound may be a copolymer of one phosphorescent compound and one carrier transporting compound, a copolymer of one phosphorescent compound and two or more carrier transporting compounds, or a copolymer of two or more phosphorescent compounds and carrier transporting compound(s).

For the sequence of monomers in the phosphorescent high molecular weight compound, the copolymer may be any of a random copolymer, a block copolymer and an alternate copolymer. When the number of a repeating unit of the phosphorescent light-emitting compound structure is designated as “m” and the number of a repeating unit of the carrier transport compound structure is designated as “n” (m and n are each an integer of 1 or more), a proportion of the number of a repeating unit of the phosphorescent light-emitting compound structure to the total number of repeating units, namely a value of {m/(m+n)} is preferably from 0.001 to 0.5, and more preferably from 0.001 to 0.2.

More specific examples and synthesis methods of the phosphorescent high molecular weight compound are disclosed in, for example, JP-A-2003-342325, JP-A-2003-119179, JP-A-2003-113246, JP-A-2003-206320, JP-A-2003-147021, JP-A-2003-171391, JP-A-2004-346312, and JP-A-2005-97589.

The light-emitting layer in the organic light-emitting element of the present invention, which is preferably a layer containing the phosphorescent compound, may contain a hole-transporting compound or an electron-transporting compound to enhance the carrier transporting ability of the light-emitting layer. As hole-transporting compounds used for this purpose, there may be mentioned, for example, low molecular triphenylamine derivatives such as TPD (N,N′-dimethyl-N,N′-(3-methylphenyl)-1,1′-biphenyl-4,4′-diamine), α-NPD (4,4′-bis[N-(1-naphthyl)-N-phenylamino]biphenyl) and m-MTDATA (4,4′,4″-tris(3-methylphenylphenylamino)triphenylamine); polyvinylcarbazole; high molecular weight compounds obtained from the triphenylamine derivative by introducing a polymerizable functional group (for example, a high molecular weight compound having a triphenylamine structure disclosed in JP-A-8-157575); poly(p-phenylenevinylene); and poly(dialkylfluorene). As the electron-transporting compounds, there may be used known electron-transporting compounds, for example, low molecular materials including metal complexes of quinolinol derivatives (for example, Alq₃ (aluminum trisquinolinolate)), oxadiazole derivatives, triazole derivatives, imidazole derivatives, triazine derivatives and triarylborane derivatives; and high molecular weight compounds obtained from the low molecular electron-transporting compound by introducing a polymerizable functional group (for example, poly PBD disclosed in JP-A-10-1665).

(6) Formation Method of the Organic EL Compound Layer:

The organic EL compound layer can be formed by coating method such as spin coating method, casting method, microgravure coating method, gravure coating method, bar coating method, roll coating method, wire bar coating method, dip coating method, spray coating method, screen printing method, flexo printing method, off-set printing method and inkjet printing method.

(7) Cathode:

The cathode used in the present invention comprises a metal-doped organic electron injection layer that is in direct contact with a transparent, non-metallic, electron-injecting cathode layer such as ITO, wherein the metal-doped organic electron injection layer functions also as an exciton-blocking layer and/or a hole-blocking layer. The metal-doped organic electron injection layer can be formed by diffusing an ultra-thin layer of highly electropositive metal throughout the layer.

A particular feature of this cathode is the use of an ultra-thin layer of electropositive metal such as lithium, which is allowed to diffuse throughout the organic election injection layer immediately adjacent to an electron-injecting cathode material such as ITO. An ultra-thin layer refers to a layer that is only of the order of about 0.5 nm-1.0 nm thick. Since the electropositive metal can readily diffuse throughout the electron injection layer, the electropositive metal may be deposited on either side or both sides of the electron injection layer.

For example, after a substrate material, an anode and an organic EL compound layer are formed, a layer of electropositive metal as an ultra-thin metallic layer may directly be deposited on the organic EL compound layer. Successively an electron injection layer is formed on this ultra-thin metallic layer, and next an ITO layer, which injects electrons, is formed on this organic electron injection layer.

Alternatively, after an organic electron injection layer is formed on an organic EL compound layer, a layer of electropositive metal may be deposited on the organic electron injection layer. In this case, an ITO layer, which injects electrons, is successively formed on the electropositive metallic layer.

According to Patent document 1, it is considered that, in each case, the electropositive metal diffuses throughout the electron injection layer to form a highly doped electron injection layer and that free electrons are donated to the electron-injecting layer from the electropositive metal. The electropositive metal is metal that easily looses or donates electrons, for example, the elements in Group 1, 2 and 3 or elements in the lanthanide group of the periodic table. Preferred electropositive metals include, for example, Li, Sr and Sm, and Li is the most preferred.

Since the thickness of ultra-thin metallic layers is limited to only about 0.5 nm-1.0 nm, it is believed that the electropositive metal diffuses substantially in its entirety into the electron injection layer so that, after such diffusion, the ultra-thin metallic layer is no longer on the surface of the electron-injecting layer. Thus, the entire cathode, which includes both the electron-injecting ITO layer and the electron injection layer, may be referred to as being non-metallic since the cathode does not contain a separate metallic layer. The metal elements indium and tin, that are present in the ITO layer, are each present in their chemically combined oxide form, whereas the electropositive metals such as lithium are diffused throughout the electron injection layer and, thus, are not present in a metallic form.

It is believed that diffusion of the electropositive metal into the electron injection layer can create a highly degenerately doped layer that enhances electron injection into the organic EL element. More specifically, it is believed that the electropositive material donates electrons to the organic electron injection layer, thereby increasing the conductivity of the electron injection layer upto such a level that band bonding occurs to aid in the injection of charge into this layer. An increased conductivity results in a reduced barrier for injecting electrons into the electron injection layer, as compared with conventional organic EL elements that do not contain electropositive metal doped in the electron injection layer. A reduction in the electron injection barrier results in a reduced operating voltage for organic EL elements that contain the metal-doped electron injection layer.

In the representative embodiment of cathode used in the present invention, in which lithium is doped in a BCP layer, it is believed that diffusion of the electropositive lithium metal into the BCP layer creates a highly degenerate metal-doped BCP layer. However, even highly doped metallic layers that are not doped sufficiently to become fully degenerate are also believed to be capable of functioning within the scope and spirit of the present invention. While it may not be known exactly what fraction of the metal atoms that diffuse into the electron injection layer may contribute to the measurable or charge-carrying electron density of the layer, the metal atom density in this layer may be selected so as to be sufficient to produce a theoretically predicted electron density, based on the assumption that each metal atom donates just one charge-carrying electron to the molecules in the electron injection layer. For example, based on this assumption, the metal atom density in this layer may be selected so as to produce an electron density between 10¹⁵/cm³ and 10²²/cm³. A metal-doped layer in the present invention, thus, has a metal atom density of at least 10¹⁵/cm³ and preferably a metal atom density of at least 10²¹/cm³.

Alternatively, the metal atom density in the electron injection layer can be tailored for producing a total external quantum efficiency greater than the efficiency of an organic EL element that uses a thick metallic cathode, while also achieving greater transparency. More specifically, the metal atom density in the electron injection layer may be selected to be sufficient to produce a total external quantum efficiency of the organic EL element of at least 1%.

A further feature of the cathode used in the present invention is the use of an exciton-blocking and/or a hole-blocking material as the organic electron injection layer that is doped with the electropositive metal. By choosing a material that permits the metal-doped organic electron injection layer to function as an exciton-blocking layer, the metal-doped organic electron injection layer serves to block diffusion of excitons into this layer, thus allowing more of the excitons within the light-emitting layer to contribute to the efficiency of the organic EL element. A material that is used as the exciton-blocking layer in an organic EL element may be defined as a material whose exciton energy, defined as the energy difference between the electron and hole in a ground state exciton, is greater than the energy of the exciton produced in the organic EL compound layer. Because of the Coulomb forces between the nearby electron and hole in the ground state exciton, the exciton energy of an organic material is typically slightly less than the energy difference between the lowest unoccupied molecular orbital (LUMO) and the highest occupied molecular orbital (HOMO) of the material.

By choosing a material that permits the metal-doped organic electron injection layer to function as a hole-blocking layer, the metal-doped organic electron injection layer serves to block diffusion of holes into the layer, thus allowing more excitons to be created within the light-emitting layer so as to contribute to increasing the efficiency of the organic EL element. The metal-doped organic electron injection layer, thus, may function as an exciton-blocking layer, as a hole-blocking layer, or as both an exciton-blocking layer and a hole-blocking layer.

Since the electron injection layer also has the function of conducting charge carriers, in particular, electrons, the ionization potential (IP) and band gap of the electron injection material are such as to provide efficient charge carrier flow into the adjacent light-emitting compound layer. The requirements and characteristics of these materials are described in specifications of U.S. patent application Ser. No. 09/153, 144 filed Sep. 14, 1998 and U.S. patent application Ser. No. 09/311,126 filed May 13, 1999.

More specific examples of production method and performances of the cathode used in the present invention can be referred to Patent document 1.

(8) Sealing:

After making, the cathode, a protective layer, which protects the organic EL element, may be formed. In order to use the organic EL element stably for a long time, it is preferred that a protective layer and/or a protective cover are mounted for protecting the element from external environment. As the protective layer, there may be used high molecular weight compounds, metal oxides, metal fluorides, metal boronides or the like. As the protective cover, there may be used a glass plate, a plastic plate processed with treatment for reducing water permeability on its surface, metal or the like. A preferably used method is a method wherein the cover is adhered to the substrate of the element with thermosetting resin or photo-curable resin for sealing. With some space maintained by using a spacer, damage to the element can be readily avoided. By incorporating inert gas such as nitrogen and argon, oxidation of the cathode can be prevented. Furthermore, placing a drying agent such as barium oxide in the space facilitates suppression of damage to the element caused by moisture that has been adsorbed in the course of the production process. It is preferred to adopt one or more of these strategies.

(9) Kind of the Substrate:

As the substrate for the organic EL element relating to the present invention, there may be used an insulating substrate that is transparent at the emission wavelength of the light-emitting compound, for example, known materials such as glass, transparent plastic including PET (polyethylene terephthalate) and polycarbonate and silicone substrate.

### Use

The organic EL element of the present invention may be used for, for example, a surface emitting source, a backlight for display device, a display device, an illumination device, interior goods and exterior goods.

1. An organic electro-luminescence element comprising an anode layer, an organic electro-luminescence compound layer containing a high molecular weight light-emitting compound, and a cathode layer, laminated in this order,
wherein said cathode layer comprises:
(i) a metal-doped electron injection layer in contact with the organic electro-luminescence compound layer and
(ii) a transparent, non-metallic electron-injecting material in contact with the metal-doped electron injection layer; and
wherein said metal-doped electron injection layer is selected from the group consisting of a material functioning as a hole-blocking material, a material functioning as an exciton-blocking material and a material functioning as a blocking material for both holes and excitons.

2. The organic electro-luminescence element according to claim 1, wherein the metal-doped electron injection layer also functions as an exciton-blocking layer.

3. The organic electro-luminescence element according to claim 1, wherein the metal-doped electron injection layer also functions as a hole-blocking layer.

4. The organic electro-luminescence element according to claim 1, wherein the metal-doped electron injection layer is doped with a metal selected from the group consisting of Li, Sr and Sm.

5. The organic electro-luminescence element according to claim 1, wherein the metal-doped electron injection layer is doped with Li.

6. The organic electro-luminescence element according to claim 1, wherein the metal-doped electron injection layer comprises 2,9-dimethyl-4,7-diphenyl-1,10-phenanthroline.

7. The organic electro-luminescence element according to claim 1, wherein the metal-doped electron injection layer has a metal atom density sufficient to produce an electronic density of at least 10¹⁵/cm³.

8. The organic electro-luminescence element according to claim 1, wherein the metal-doped electron injection layer has a metal atom density sufficient to produce an electronic density of at least 10²¹/cm³.

9. The organic electro-luminescence element according to claim 1, wherein the metal-doped electron injection layer has a metal atom density sufficient to produce a total external quantum efficiency of at least 1% for the above-mentioned organic electro-luminescence element.

10. The organic electro-luminescence element according to claim 1, wherein the organic electro-luminescence compound layer comprises a phosphorescent high molecular weight compound.

11. The organic electro-luminescence element according to claim 1, wherein the organic electro-luminescence compound layer comprises a non-conjugated high molecular weight light-emitting compound.

12. The organic electro-luminescence element according to claim 1, wherein the organic electro-luminescence compound layer comprises a phosphorescent non-conjugated high molecular weight compound.

13. A surface emitting source equipped with the organic electro-luminescence element according to claim 1.

14. A backlight for a display device equipped with the organic electro-luminescence element according to claim 1.

15. A display device equipped with the organic electro-luminescence element according to claim 1.

16. An illumination device equipped with the organic electro-luminescence element according to claim 1.

17. Interior goods equipped with the organic electro-luminescence element according to claim 1.

18. Exterior goods equipped with the organic electro-luminescence element according to claim 1.

19. A production method of an organic electro-luminescence element comprising:
preparing, in sequence on a substrate, an anode layer, an organic electro-luminescence compound layer containing a high molecular weight light-emitting compound, a transparent electron injection layer and a transparent electron-injecting layer,
wherein said transparent electron injection layer is a material selected from the group consisting of a material functioning as a hole-blocking layer, a material functioning as an exciton-blocking layer and a material functioning as a blocking layer for both holes and excitons; and
wherein the preparation comprises a step of doping the transparent electron injection layer with metal to form a metal-doped transparent electron injection layer.

20. The production method according to claim 19 comprising, before forming a film of the transparent electron injection layer, doping the metal into the transparent electron injection layer by vapor depositing an ultra-thin layer of the metal onto the organic electron-transporting layer.

21. The production method according to claim 19 comprising, before forming a film of the transparent electron-injecting layer, doping the metal into the transparent electron injection layer by vapor depositing an ultra-thin layer of the metal onto the transparent electron injection layer.

22. The production method according to claim 19, wherein the electron-injecting layer comprises ITO.

23. The production method according to claim 20, wherein the thickness of the ultra-thin layer of metal is 0.5-1.0 nm.

24. The production method according to claim 20, wherein the metal comprises a metal selected from the group consisting of Li, Sr and Sm.

25. The production method according to claim 20, wherein the metal comprises Li.

26. The production method according to claim 19, wherein the metal-doped transparent electron injection layer comprises 2,9-dimethyl-4,7-diphenyl-1,10-phenanthroline.

27. The production method according to claim 19, wherein the metal-doped transparent electron injection layer has a metal atom density sufficient to produce an electronic density of at least 10¹⁵/cm³.

28. The production method according to claim 19, wherein the metal-doped transparent electron injection layer has a metal atom density sufficient to produce an electronic density of at least 10²¹/cm³.

29. The production method according to claim 19, wherein the metal-doped transparent electron injection layer has a metal atom density sufficient to produce a total external quantum efficiency of at least 1% for the organic electro-luminescence element.

30. The production method according to claim 19, wherein the organic electro-luminescence compound layer comprises a phosphorescent high molecular weight compound.

31. The production method according to claim 19, wherein the organic electro-luminescence compound layer comprises a light-emitting non-conjugated high molecular weight compound.

32. The production method according to claim 19, wherein the organic electro-luminescence compound layer comprises a phosphorescent non-conjugated high molecular weight compound.
